(19) United States
(12) Patent Application Publication
(10) Pub. No.: US 2005/0285116 A1
(43) Pub. Date: Dec. 29, 2005

(54) Electronic assembly with carbon nanotube contact formations or interconnections

(76) Inventor: Yongqian Wang, Gilbert, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/881,041

(22) Filed: Jun. 29, 2004

(51) Int. Cl. H01L 29/15

(52) U.S. Cl. 257/76

(57) ABSTRACT

According to one aspect of the invention, an electronic assembly is provided. The electronic assembly includes a microelectronic die having an integrated circuit formed therein. Carbon nanotubes are grown on the microelectronic die and are electrically connected to the integrated circuit. The carbon nanotubes form a plurality of contact formations to connect the die, and the integrated circuit therein, to a package substrate. The package substrate may then be attached to a printed circuit board and installed in a computing system. According to another aspect of the present invention, a first conductive layer is formed on a semiconductor substrate having a plurality of transistors formed thereon. Then a second conductive layer is formed on the first conductive layer. A hole is created at least partially through both the first and second conductive layers. Carbon nanotubes are grown within the hole to electrically interconnect the two conductive layers.

### BACKGROUND OF THE INVENTION

1). Field of the Invention

Embodiments of this invention relate to an electronic assembly, and more particularly, how electrical connections are made between various components of the electronic assembly.

2). Discussion of Related Art

Integrated circuits are formed on semiconductor wafers. The wafers are then sawed (or “singulated” or “diced”) into microelectronic dice, also known as semiconductor chips, with each chip carrying a respective integrated circuit. Each semiconductor chip is then mounted to a package, or carrier, substrate. Often the packages are then mounted to a motherboard, which may then be installed into a computing system.

The package substrates provide structural integrity to the semiconductor chips and are used to connect the integrated circuits electrically to the motherboard. On the side of the of the package substrate connected to the motherboard there are Ball Grid Array (BGA) solder ball contact formations, which are soldered to the motherboard. Electric signals are sent through BGA formations into and out of the package.

On the side of the microelectronic dice that are connected to the package there are other, smaller solder contact formations, such as controlled-collapse chip connections (C4) contact formations. The electric signals are sent between the package and the microelectric die through the C4 contact formations.

Currently, the smallest possible pitch, or distance between the C4 contact formations, is approximately 100 microns, while the smallest possible size of a contact formation has a diameter of approximately 40 microns. If contact formations with smaller pitches or sizes are made with modern soldering techniques, the resulting semiconductor package is inherently unreliable. The bond between the die and the package substrate is not strong enough due to the small size of the solder ball. Additionally, because of the small size of the solder ball (and joint) and the limited electrical and thermal conductivity of the solder, the solder balls (and/or joints) melt as the integrated circuits within the dice reach state of the art performance levels with high power outputs. Similar problems are found with the use of metals, such as copper, for interconnects and vias which electrically connect conductive layers within the semiconductor chips.

### BRIEF DESCRIPTION OF THE DRAWINGS

Embodiments of the invention are described by way of examples with reference to the accompanying drawings, wherein:

FIG. 1A is a top plan view of a semiconductor wafer;

FIG. 1B is a cross-sectional side view of the semiconductor wafer of FIG. 1A;

FIG. 2A is a cross-sectional side view of a microelectronic die, or a portion of the semiconductor wafer of FIG. 1A;

FIG. 2B is a cross-sectional side view of the microelectronic die with a bonding pad formed thereon;

FIG. 2C is a cross-sectional side view of the microelectronic die with a polyimide layer formed thereon;

FIG. 2D is a cross-sectional side view of the microelectronic die with a photoresist layer formed over the polyimide layer;

FIG. 2E is a cross-sectional side view of the microelectronic die with an under bump metallurgy (UBM) layer formed over the polyimide layer and the bonding pad;

FIG. 2F is a cross-sectional side view of the microelectronic die after carbon nanotubes have been grown on the UBM layer;

FIG. 2G is a cross-sectional side view of the microelectronic die after the photoresist layer has been removed and a contact formation has been formed;

FIG. 3A is a perspective view of the semiconductor wafer after the contact formations have been formed;

FIG. 3B is a perspective view of the semiconductor wafer after the semiconductor wafer has been singulated into individual microelectronic dice;

FIG. 4 is a perspective view of a package substrate with one of the dice mounted thereon;

FIG. 5 is a perspective view of a printed circuit board with the package substrate of FIG. 4 attached thereto;

FIG. 6A is a cross-sectional side view of a microelectronic die, or a portion of a semiconductor wafer;

FIG. 6B is a cross-sectional side view of the die after a photoresist layer has been formed thereon;

FIG. 6C is a cross-sectional side view of the die after an interconnect opening has been formed therein;

FIG. 6D is a cross-sectional side view of the die after catalysts have been deposited within the interconnect opening;

FIG. 6E is a cross-sectional side view of the microelectronic die after carbon nanotubes have been grown within the interconnect opening;

FIG. 6F is a cross-sectional side view of the microelectronic die after the photoresist layer has been removed; and

FIG. 7 is a block diagram of a computing system.

### DETAILED DESCRIPTION OF THE INVENTION

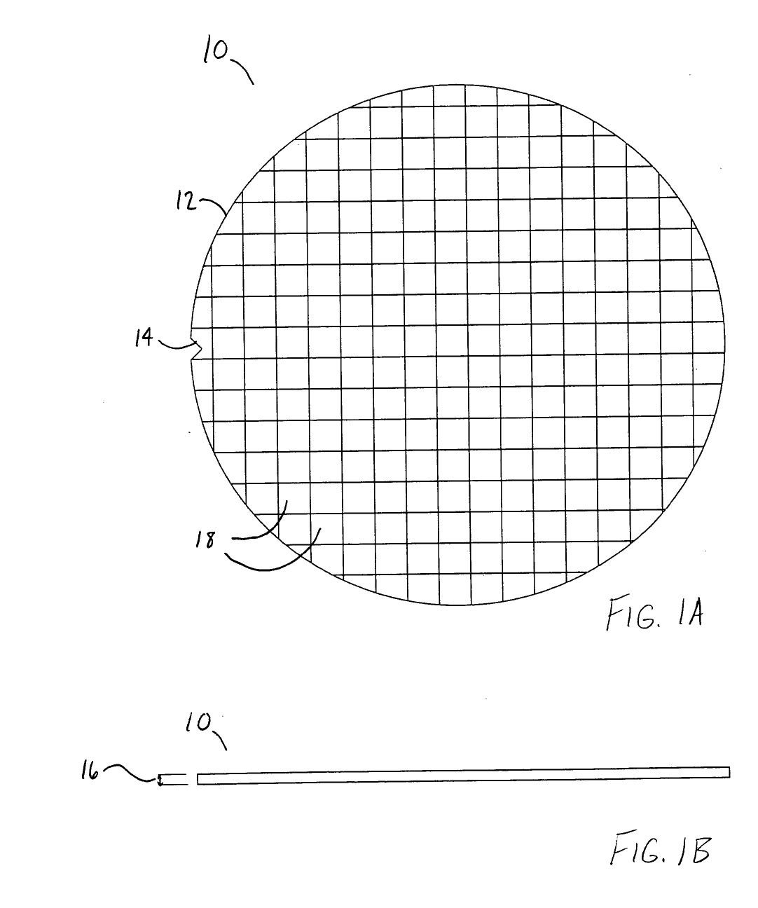

FIG. 1A to FIG. 7 illustrate electronic assemblies according to embodiments of the present invention. According to one aspect of the present invention, an electronic assembly includes a microelectronic die having an integrated circuit formed therein. Carbon nanotubes are grown on the microelectronic die and are electrically connected to the integrated circuit. The carbon nanotubes form a plurality of contact formations to connect the die, and the integrated circuit therein, to a package substrate. The package substrate may then be attached to a printed circuit board and installed in a computing system. According to another aspect of the present invention, a first conductive layer is formed on a semiconductor substrate having a plurality of transistors formed thereon. Then a second conductive layer is formed on the first conductive layer. A hole is created at least partially through both the first and second conductive layers. Carbon nanotubes are grown within the hole to electrically interconnect the two conductive layers.

It should be understood that FIGS. 1 to 7 are merely illustrative and may not be drawn to scale.

FIGS. 1A and 1B illustrate a typical semiconductor wafer 10. The semiconductor wafer has a circular outer edge 12, which is circular, typically has a diameter of 200 or 300 millimeters, and an indicator 14 thereon. The semiconductor wafer 10 typically has a thickness 16 of 0.7 millimeters and a plurality of integrated circuits, separated amongst multiple dice 18, formed thereon.

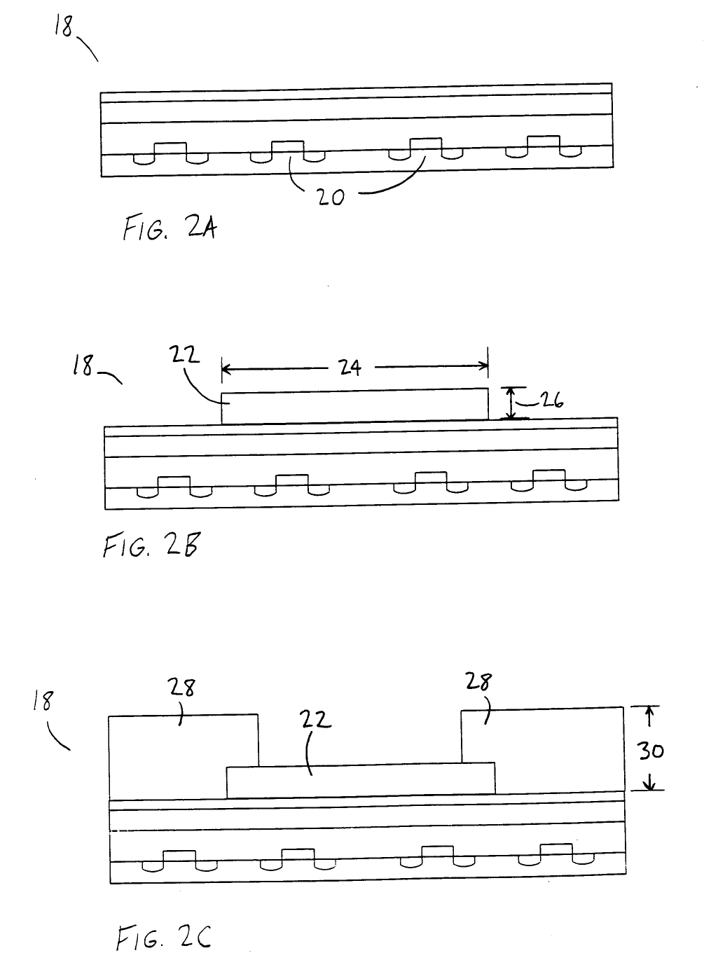

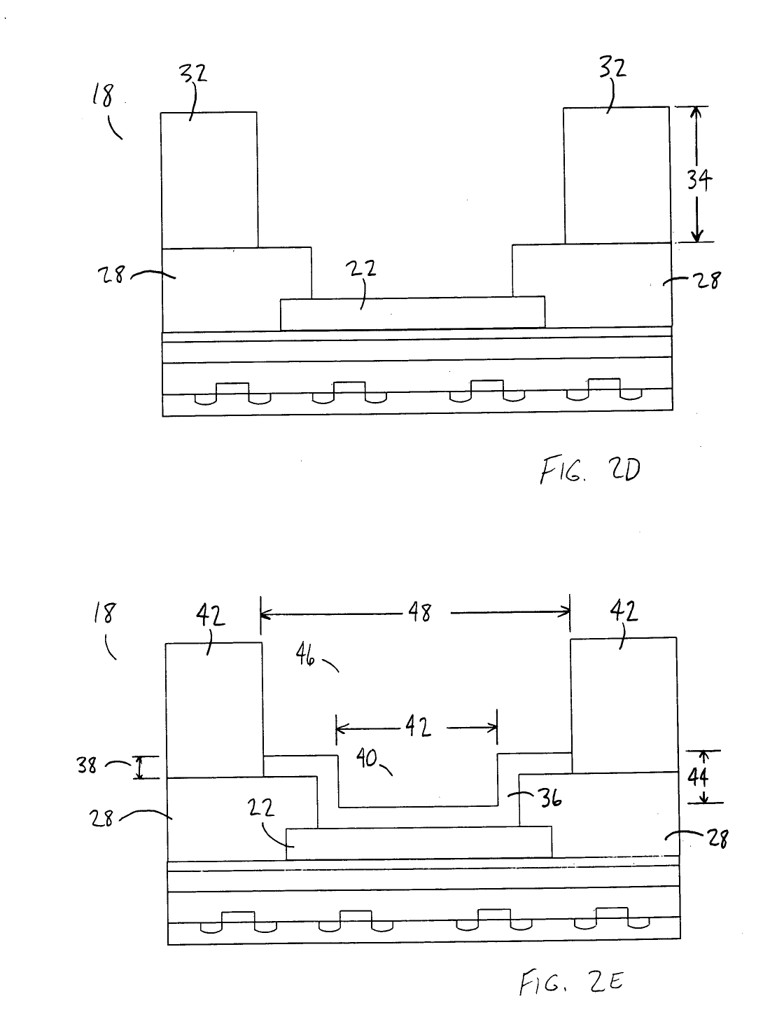

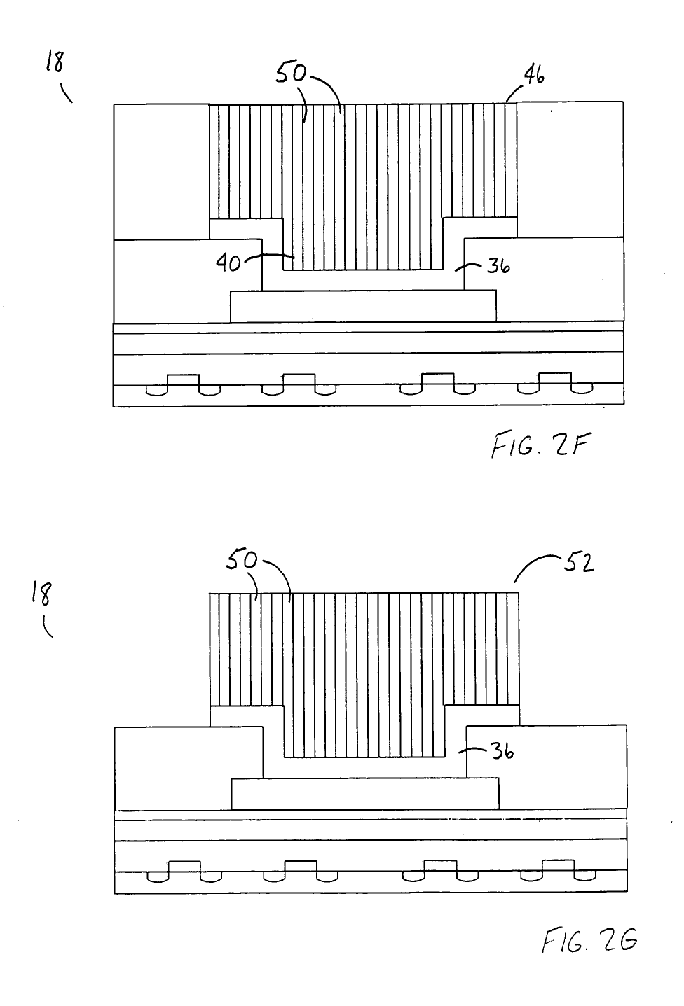

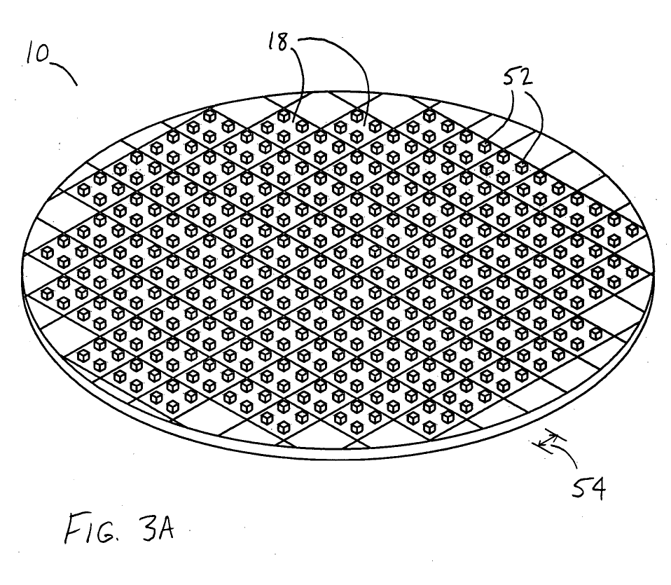

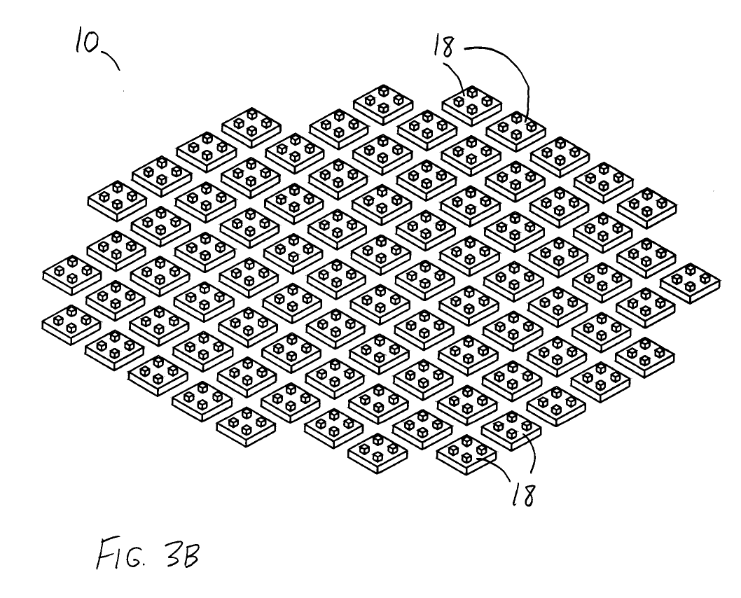

FIG. 2A illustrates one of the dice 18, or another portion of the semiconductor wafer 10. The die 18 includes an integrated circuit, such as a microprocessor, formed therein, which includes multiple transistors 20. The die 18 also includes a plurality of alternating insulating and conducting layers, as is commonly understood in the art.

FIG. 2B illustrates the die 18 with a bonding pad 22 formed thereon. The bonding pad 22 has a width 24 of 60 nm and a thickness 26 of 10 nm. The bonding pad is made of copper and is formed using electroplating. The bonding pad 22 is electrically connected to the integrated circuit within the die 18.

FIG. 2C illustrates the die 18 with a polyimide layer 28 formed on the upper surface thereof and the outer portions of the bonding pad 22. The polyimide layer 28 has a thickness 30 of 2 microns and although illustrated as not covering the entire bonding pad 22, it should be understood that the process illustrated may include covering the entire bonding pad 22 with the layer of polyimide 28 and then etching the polyimide over the central portion of the bonding pad 22.

FIG. 2D illustrates the die 18 with a photoresist layer 32 formed over the polyimide layer 28. The photoresist layer 32 has a thickness 34 of 5 microns. Although illustrated as not covering the entire die 18, it should be understood the process illustrated may include covering the entire bonding pad 22 and polyimide layer 28 with the photoresist layer 32 and then etching the photoresist layer to expose a central portion of the bonding pad 22 and a portion of the polyimide layer 28.

FIG. 2E illustrates the die 18 with an UBM layer 36 formed over the bonding pad 22 and the polyimide layer 28. The UBM layer 36 has a thickness 38 of approximately 1 micron. A depression 40 is formed over the bonding pad 22. The depression 40 has a width 42 of approximately 50 nm and a depth 44 of approximately 20 nm. The UBM layer 36 includes a nickel catalyst for growing carbon nanotubes. A bump hole 46 has now been formed in the photoresist layer 42 and the UBM layer 36 is now exposed. The bump hole 46 has width 48, of 55 nm. The UBM layer 36 is formed by sputtering.

FIG. 2F illustrates the die 18 with carbon nanotubes 50 having been grown from the UBM layer 36 to fill the depression 40 and the bump hole 46. The carbon nanotubes are multi-walled and are cylindrical with diameters of between 1 and 2 nm. The carbon nanotubes 50 are grown from and chemically bonded to the nickel catalysts within the UBM layer 32. The carbon nanotubes 50 may be grown such that each carbon nanotube 50 extends substantially perpendicular to an upper surface of the die 18 by applying an electric field during the growing process. The carbon nanotubes 50 are grown using known chemical vapor deposition (CVD) techniques.

FIG. 2G illustrates the die 18 with the photoresist layer 42 having been removed from the UBM layer 32 and from around the carbon nanotubes 50. A contact formation 52 is now formed by the carbon nanotubes 50, which extends from the UBM layer 32. The contact formation 52 has a height similar to the thickness of the photoresist layer 42 above an upper surface of the UBM layer 32, or an upper surface of the polyimide layer 28.

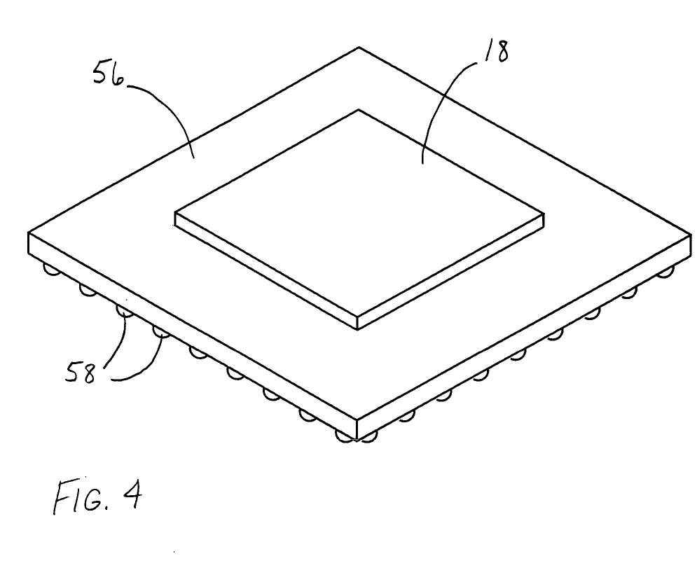

FIG. 3A illustrates the wafer 10 with contact formations 52 formed on each of the dice 18. As illustrated, each die 18 includes four contact formations 52. However, it should be understood that each die 18 may contain literally dozens (or more) of contact formations 52. The contact formations 52 are arranged on the die with a pitch 54, or distance between, of approximately 50 nm.

FIG. 3B illustrates the semiconductor wafer 10 after the dice 18 have been singulated from the semiconductor wafer 10.

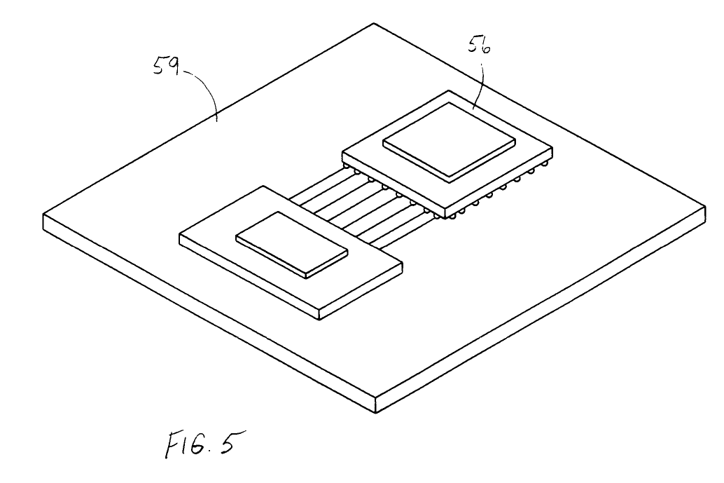

FIG. 4 illustrates a package substrate 56 with one of the cingulated dice 18 attached to top surface at a central portion thereof. The die 18 is square with side lengths of, for example, 1.5 cm. The package substrate 56 includes a plurality of BGA solder ball contact formations 58 formed on a bottom surface thereof. The package substrate 56 is square with, for example, side lengths of 3 cm and a thickness of 3 mm. The package substrate 56 has alternating conducting and insulating layers therein, as is commonly understood in the art.

FIG. 5 illustrates the package substrate 56 attached to a printed circuit board 59, such as a motherboard. The motherboard 59 is a large silicon plane having a plurality of sockets for securing and providing electric signals to various package substrates, microelectronic dice, and other electronic devices, as well as conductive traces to electrically connect such devices, as is commonly understood in the art. Although not illustrated in detail, the solder balls 58 have been heated and have bonded to one of the sockets on the motherboard 59.

In use, the motherboard 59 is installed in a computing system. Electric signals such as input/output (IO) signals, are then sent from the integrated circuit within the die 18 through the contact formations 52, into the package substrate 56, and into the computing system through the printed circuit board. Power and ground signals are also provided to the die. The computing system may send similar, or different, signals back to the integrated circuit within the die 18 through the motherboard 59, the package substrate 58, and the contact formations 52.

One advantage is that because of the small size of the contact formations made from the carbon nanotubes, the pitch of the contact formations may be minimized. Another advantage is that because of the high electrical and thermal connectivity of the carbon nanotubes, an increased amount of current may be sent through the contact formations without the contact formations being damaged by over heating. A further advantage is that because of the high physical strength of the carbon nanotubes, the die is more securely fastened to the package substrate, more reliable connections between the die and the package substrate are provided.

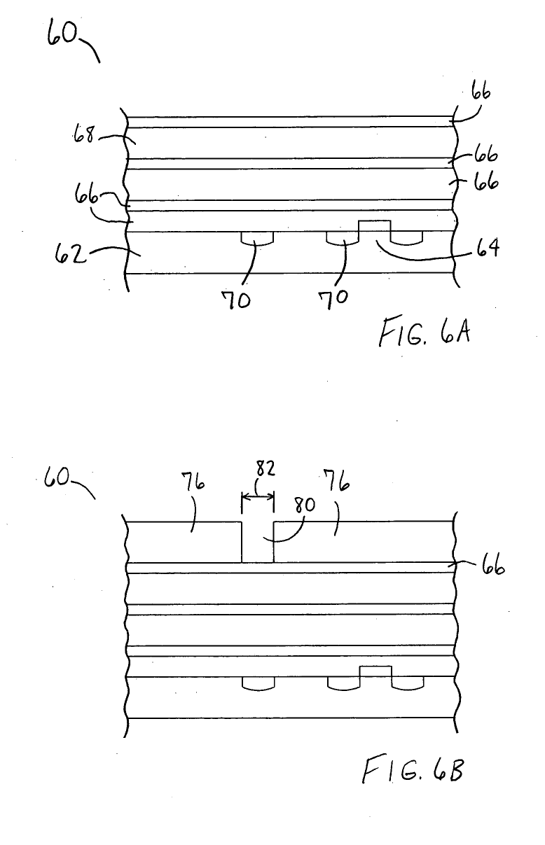

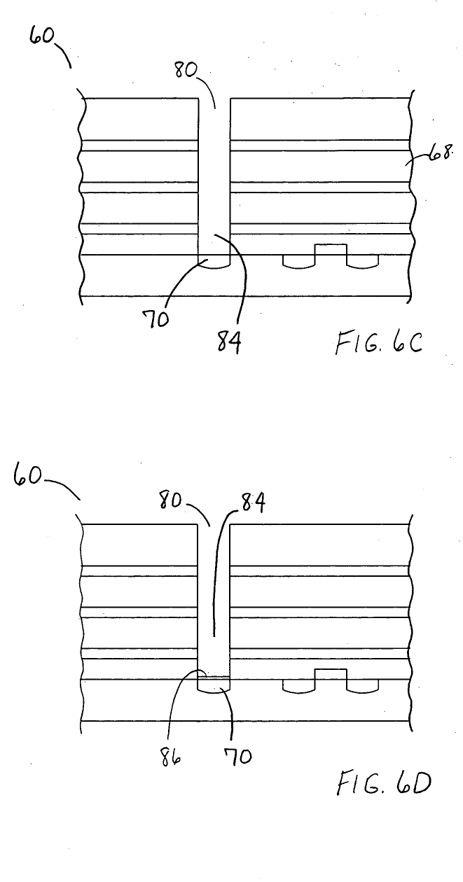

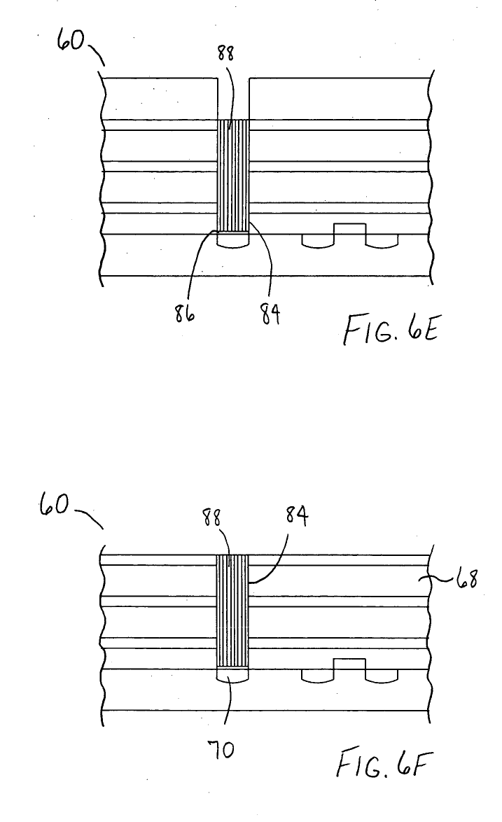

FIG. 6A illustrates a portion of a die 60, or a portion of a semiconductor wafer, similar to that illustrated in FIG. 1A. The die 60 includes a silicon substrate 62, transistors 64 formed thereon, various insulating and etch stop layers 66, and a conductive layer 68. The insulating and etch stop layers 66 are formed over the transistors 64. The silicon substrate 62 further includes source/drain/gate regions with electrodes 70 formed above, which are essentially additional conductive layers or lines. The conductive layer 68 and the source and drain electrodes 70 are made of electroplated copper and other conductive materials. The conductive layer 68 has a thickness of 10 microns.

FIG. 6B illustrates the die 60 with a photoresist layer 76 formed on an upper most etch stop layer 66. The photoresist layer 76 has a thickness of 20 microns. As illustrated in FIG. 6B, the photoresist layer 76 has undergone a photo lithography process and an interconnect trench 80 has been formed thereon, leaving the uppermost etch stop layer 66 exposed. The interconnect trench 80 has a width 82 of approximately 20 nm.

FIG. 6C illustrates the die 60 after having undergone an etching process. The die 60 now has an interconnect opening 84, beneath the interconnect trench 80, that extends through the conductive layer 68 as well as the insulating and etch stop layers 66 to one of the source/drain/gate electrodes 70.

FIG. 6D illustrates the die 60 after a nickel catalyst 86 has been deposited onto the bottom of the interconnect opening 84 and on the source/drain/gate electrode 70. The nickel catalyst 86 is deposited using plasma vapor deposition (PVD).

FIG. 6E illustrates the die 60 after carbon nanotubes 88 have been grown within the interconnect opening 84 from the catalyst 86. The carbon nanotubes 88 are formed using CVD and chemically bonded to the catalyst 86.

FIG. 6F illustrates the die 60 after the photoresist layer 76 has been removed from the upper surface of the die 60. As illustrated, the carbon nanotubes 88 completely fill the interconnect opening 84 and interconnect the source/drain/gate electrode 70 and the conductive layer 68 to form an interconnect or via.

Although not illustrated, it should be understood that multiple interconnects may be formed within the die which may have a distance between the interconnects similar to the pitch 54 of the contact formations illustrated in FIG. 3A.

In use, after the semiconductor wafer of which the die 60 is part has undergone all necessary processing steps, which may include formation of the contact formations as illustrated in FIGS. 2H, 3A, and 3B, the wafer is singulated and the die 60 may be mounted to a package substrate, similar to the one illustrated in FIG. 4, attached to a printed circuit board, such as a motherboard similar to the one illustrated in FIG. 5, and installed within a computing system.

An electric current is supplied by the computing system to the integrated circuit within the die 60 through the printed circuit board, the BGA formations, and the package substrate. Electric signals, such as 10 signals, are then sent from the integrated circuit within the die to the computing system. Power and ground signals are also provided to the die. Then other electric signals may be sent back to the integrated circuit through a similar pathway. The electric signals conduct between the conductive layer 68 and the source or drain region 70 through the carbon nanotube interconnects.

Other embodiments may use different methods to grow the carbon nanotubes, such as discharge between between carbon electrodes, laser vaporation of carbon, thermal decomposition of hydrocarbons such as acetylene, methane, and ethane, and plasma enhanced chemical vapor deposition. Different catalysts may be used to grow the carbon nanotubes such as cobalt, iron, rhodium platinum, nickel yttrium, or any combination thereof. Other conductive materials may be used to form the conductive layers within the dice, such as gold, aluminum, and tungsten. The carbon nanotubes interconnects may be used to electrically connect other conductive components within the die, such as two upper conductive layers, rather than one of the upper conductive layers and a source/drain/gate electrode of one of the transistors. The carbon nanotube contact formations and interconnects may be formed of different sizes and with pitches (such as less than 100 microns and less than 20 microns) different than that illustrated in FIG. 3A.

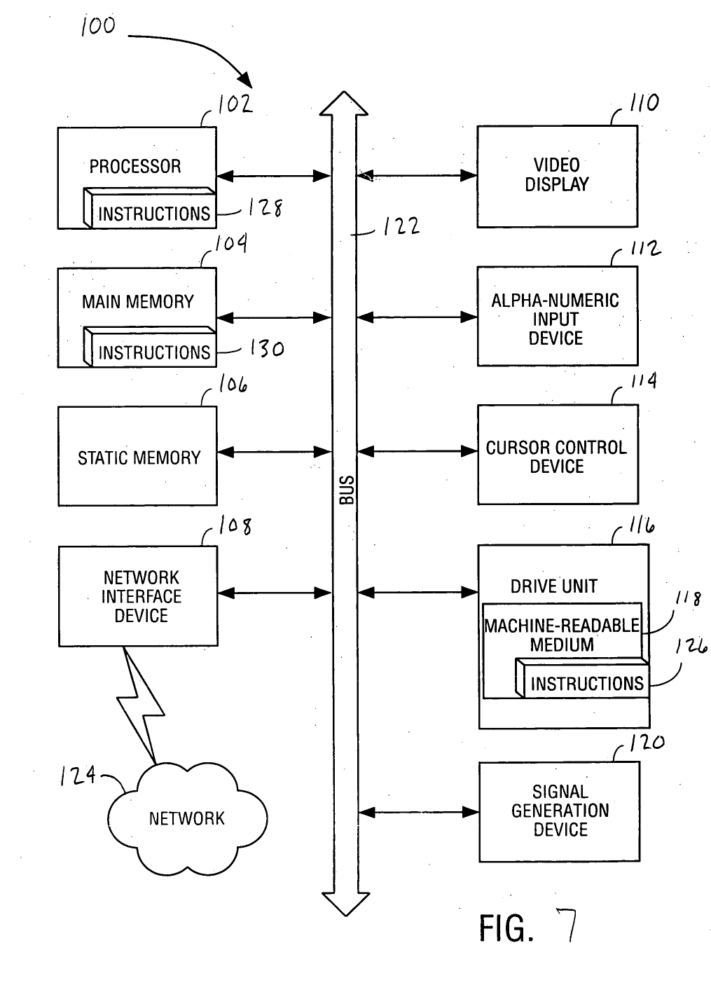

FIG. 7 illustrates a computing system 100 into which the dice, packages, and printed circuit boards described above may be installed. The computing system includes a processor 102, a main memory 104, a static memory 106, a network interface device 108, a video display 110, an alpha-numeric input device 112, a cursor control device 114, a drive unit 116 including a machine-readable medium 118, and a signal generation device 120. All of the components of the computing system 100 are interconnected by a bus 122. The computing system 100 may be connected to a network 124 through the network interface device 108.

The machine-readable medium 118 includes a set of instructions 126, which may be partially transferred to the processor 102 and the main memory 104 through the bus 122. The processor 102 and the main memory 104 may also have separate internal sets of instructions 128 and 130.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A method of forming a contact formation comprising:
growing a plurality of carbon nanotubes from a semiconductor substrate having at least one integrated circuit formed thereon, the carbon nanotubes having a first portion electrically connected to the at least one integrated circuit and a second portion to connect to a computing system.

2. The method of claim 1, wherein the carbon nanotubes form a plurality of contact formations, each contact formation being electrically connected to the at least one integrated circuit.

3. The method of claim 2, wherein the semiconductor substrate is a wafer having a plurality of integrated circuits formed thereon.

4. The method of claim 2, wherein the contact formations are arranged to have a pitch of less than 100 microns.

5. The method of claim 4, wherein the contact formations are arranged to have a have a pitch of less than 20 microns.

6. The method of claim 5, wherein the contact formations are arranged to have a pitch of approximately 50 nanometers and the contact formations have a width of approximately 50 nanometers.

7. The method of claim 6, further comprising forming bonding pads on the semiconductor substrate, the bonding pads being between the contact formations and the integrated circuits.

8. The method of claim 7, further comprising depositing a catalyst on the semiconductor substrate, the carbon nanotubes being chemically bonded to the catalyst.

9. A method comprising:
growing plurality of carbon nanotubes from a microelectronic die having an integrated circuit form thereon, the carbon nanotubes being electrically connected to the integrated circuit; and
attaching the microelectronic die to a package substrate including plurality of alternating conducting and insulating layers formed therein, the integrated circuit being electrically connected to the conducting layers through the carbon nanotubes.

10. The method of claim 9, wherein the carbon nanotubes form a plurality of contact formations being electrically connected to the integrated circuit, the contact formations being arranged to have a pitch of less than 20 microns.

11. The method of claim 10, further comprising depositing a catalyst on the microelectronic die, the contact formations having first portions being chemically bonded to the catalyst and second portions extending a height from a surface of the microelectronic die.

12. A method comprising:
forming a first conductive layer on a semiconductor substrate having a plurality of transistors formed thereon;
forming a second conductive layer over the first conductive layer; and
growing a plurality of carbon nanotubes on the semiconductor substrate, the carbon nanotubes electrically interconnecting the first and second conductive layers.

13. The method of claim 12, further comprising forming a first etch stop layer on the semiconductor substrate beneath the first conductive layer, a second etch stop layer on the first conductive layer, and a third etch stop layer on the second conductive layer.

14. The method of claim 13, further comprising etching an interconnection opening through the second conductive layer and at least partially through the first conductive layer, said growth of the carbon nanotubes taking place within the interconnection opening.

15. The method of claim 14, further comprising depositing a catalyst at a bottom of the interconnection opening, the carbon nanotubes being chemically bonded to the catalyst.

16. An electronic assembly comprising:
a substrate having a plurality of alternating conducting and insulating layers and at least one integrated circuit formed thereon and a surface; and
a plurality of carbon nanotubes having first portions attached to the substrate and second portions extending a height above the surface of the semiconductor substrate, the carbon nanotubes being electrically connected to the at least one integrated circuit.

17. The electronic assembly of claim 16, wherein the carbon nanotubes form a plurality of contact formations, each contact formation being electrically connected to the at least one integrated circuit.

18. The electronic assembly of claim 17, wherein the semiconductor substrate is a wafer having a plurality of integrated circuits formed thereon.

19. The electronic assembly of claim 18, wherein the contact formations are arranged to have a pitch of less than 100 microns.

20. The electronic assembly of claim 19, wherein the contact formations are arranged to have a pitch of less than 20 microns.

21. The electronic assembly of claim 20, wherein the contact formations are arranged to have a pitch of approximately 50 nanometers and the contact formations have a width of approximately 50 nanometers.

22. The electronic assembly of claim 21, further comprising bonding pads on the semiconductor substrate, the bonding pads being between the contact formations and the integrated circuits.

23. The method of claim 22, further comprising a catalyst deposited on the semiconductor substrate, the carbon nanotubes being chemically bonded to the catalyst.

24. An electronic assembly comprising:
a package substrate including plurality of alternating conducting and insulating layers formed therein; and
a microelectronic die mounted to a surface of the package substrate, the microelectronic die having an integrated circuit formed thereon and a plurality of carbon nanotubes electrically interconnecting the integrated circuit and the conducting layers within the package substrate.

25. The electronic assembly of claim 24, wherein the carbon nanotubes form a plurality of contact formations being electrically connected to the integrated circuit, the contact formations having a pitch of less than 20 microns.

26. The electronic assembly of claim 25, further comprising a catalyst deposited on the microelectronic die, the contact formations having first portions being chemically bonded to the catalyst and second portions extending a height from a surface of the microelectronic die.

27. The electronic assembly of claim 26, wherein the microelectronic die is a processor and further comprising a printed circuit board and a memory attached to the printed circuit board, the package substrate being attached to the printed circuit board and the processor being electrically connected to the memory through the package substrate and the printed circuit board.

28. An electronic assembly comprising:
a semiconductor substrate having a plurality of transistors formed therein;
a first conductive layer formed on the semiconductor substrate;
an insulating layer over the first conductive layer;
a second conductive layer formed on the first conductive layer; and
at least one carbon nanotube extending through the insulating layer and electrically interconnecting the first and second conductive layers.

29. The electronic assembly of claim 28, wherein the semiconductor substrate is a microelectronic die.

30. The electronic assembly of claim 29, wherein the microelectronic die is a processor and further comprising a printed circuit board and a memory attached to the printed circuit board, the package substrate being attached to the printed circuit board and the processor being electrically connected to the memory through the package substrate and the printed circuit board.
